(19) United States
(12) Patent Application Publication
(10) Pub. No.: US 2024/0055332 A1
(43) Pub. Date: Feb. 15, 2024

(54) SEMICONDUCTOR DEVICE

(71) Applicant: ROHM CO., LTD., Kyoto-shi (JP)

(72) Inventor: Xiaopeng WU, Kyoto-shi (JP)

(21) Appl. No.: 18/493,353

(22) Filed: Oct. 24, 2023

Related U.S. Application Data
(63) Continuation of application No. PCT/JP2022/022583, filed on Jun. 3, 2022.

(30) Foreign Application Priority Data
Jun. 14, 2021 (JP) 2021-098928

(51) Int. Cl. H01L 23/495; H01L 23/00; H01L 23/31

(52) U.S. Cl. CPC H01L 23/49568; H01L 23/49575; H01L 24/32; H01L 24/30; H01L 23/49562; H01L 23/3107; H01L 24/29; H01L 24/83; H01L 2224/32245; H01L 2224/30181; H01L 2224/29124; H01L 2224/29639; H01L 2224/83447

(57) ABSTRACT

A semiconductor device includes: a first conductive plate and a second conductive plate spaced apart from each other in a direction x; a third conductive plate facing the first and second conductive plates in a direction z; a first semiconductor element arranged between the first conductive plate and the third conductive plate; a second semiconductor element arranged between the second conductive plate and the third conductive plate; a positive input terminal electrically connected to the first conductive plate; a negative input terminal electrically connected to the second conductive plate; an output terminal electrically connected to the third conductive plate; and a sealing resin covering at least the first and second semiconductor elements.

### TECHNICAL FIELD

The present disclosure relates to a semiconductor device.

### BACKGROUND ART

Semiconductor devices including semiconductor elements have been proposed in a variety of configurations. JP-A-2020-47758 discloses an example of a conventional semiconductor device. The semiconductor device disclosed in JP-A-2020-47758 includes a lead, two semiconductor elements, and a sealing resin. Each of the two semiconductor elements is a transistor having a switching function, and is mounted on the lead. The sealing resin covers a portion of the lead and the two semiconductor elements. A reverse surface (a surface opposite to the mounting surface for the semiconductor elements) of the lead is exposed from the sealing resin. With this configuration, the heat generated in the semiconductor elements can be transferred to the lead and released from the reverse surface of the lead. In such a semiconductor device, two semiconductor elements are mounted on a lead. As such, the amounts of heat transferred from the two semiconductor elements may interfere with each other at the lead, and may cause lowering of the heat dissipation property.

### BRIEF DESCRIPTION OF THE DRAWINGS

FIG. 1 is a perspective view showing a semiconductor device according to a first embodiment of the present disclosure.

FIG. 2 is a perspective view showing the semiconductor device according to the first embodiment of the present disclosure (with the sealing resin shown in phantom).

FIG. 3 is a plan view showing the semiconductor device in FIG. 1 (with the sealing resin shown in phantom).

FIG. 4 is a front view showing the semiconductor device in FIG. 1.

FIG. 5 is a plan view showing the semiconductor device in FIG. 1 (with the sealing resin shown in phantom and a third conductive plate and a second semiconductor element omitted).

FIG. 6 is a cross-sectional view taken along line VI-VI in FIG. 3.

FIG. 7 is a cross-sectional view taken along line VII-VII in FIG. 3.

FIG. 8 is a cross-sectional view taken along line VIII-VIII in FIG. 3.

FIG. 9 is a cross-sectional view taken along line IX-IX in FIG. 3.

FIG. 10 is a partially enlarged view of FIG. 6.

FIG. 11 is a partially enlarged view of FIG. 6.

FIG. 12 shows an example of the circuit configuration of the semiconductor device according to the first embodiment of the present disclosure.

FIG. 13 is a cross-sectional view showing a semiconductor device according to a second embodiment of the present disclosure.

FIG. 14 is a cross-sectional view showing a semiconductor device according to a third embodiment of the present disclosure.

FIG. 15 is a cross-sectional view showing a semiconductor device according to a fourth embodiment of the present disclosure.

FIG. 16 is a cross-sectional view showing a semiconductor device according to a fifth embodiment of the present disclosure.

FIG. 17 is a plan view showing a semiconductor device according to a sixth embodiment of the present disclosure (with a sealing resin shown in phantom).

FIG. 18 is a cross-sectional view taken along line XVIII-XVIII in FIG. 17.

FIG. 19 is a cross-sectional view taken along line XIX-XIX in FIG. 17.

FIG. 20 is a plan view showing a semiconductor device according to a seventh embodiment of the present disclosure (with a sealing resin shown in phantom).

FIG. 21 is a cross-sectional view taken along line XXI-XXI in FIG. 20.

FIG. 22 is a cross-sectional view taken along line XXII-XXII in FIG. 20.

FIG. 23 is a plan view showing a semiconductor device according to an eighth embodiment of the present disclosure (with a sealing resin shown in phantom).

### DETAILED DESCRIPTION OF EMBODIMENTS

Preferred embodiments of the present disclosure are described below with reference to the accompanying drawings.

In the present disclosure, the terms such as “first”, “second”, and “third” are used merely as labels and are not necessarily intended to impose orders on the items to which these terms refer.

In the present disclosure, the phrases “an object A is formed in an object B” and “an object A is formed on an object B” include, unless otherwise specified, “an object A is formed directly in/on an object B” and “an object A is formed in/on an object B with another object interposed between the object A and the object B”. Similarly, the phrases “an object A is disposed in an object B” and “an object A is disposed on an object B” include, unless otherwise specified, “an object A is disposed directly in/on an object B” and “an object A is disposed in/on an object B with another object interposed between the object A and the object B”. Similarly, the phrase “an object A is located on an object B” includes, unless otherwise specified, “an object A is located on an object B in contact with the object B” and “an object A is located on an object B with another object interposed between the object A and the object B”. Furthermore, the phrase “an object A overlaps with an object B as viewed in a certain direction” includes, unless otherwise specified, “an object A overlaps with the entirety of an object B” and “an object A overlaps with a portion of an object B”.

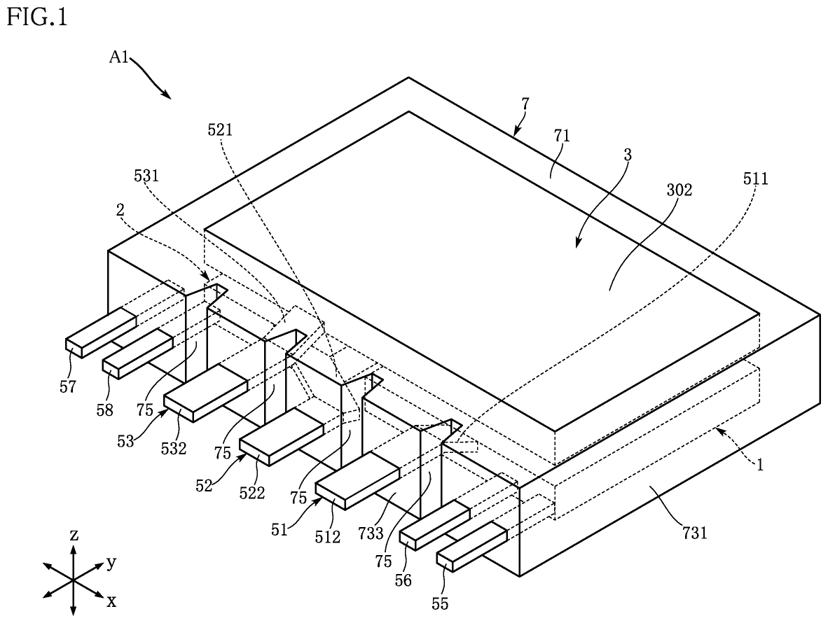

FIGS. 1 to 12 show a semiconductor device according to a first embodiment of the present disclosure. A semiconductor device A1 of the present embodiment includes a first conductive plate 1, a second conductive plate 2, a third conductive plate 3, a first semiconductor element 41, a second semiconductor element 42, a first input terminal 51, a second input terminal 52, an output terminal 53, first control terminals 55 and 56, second control terminals 57 and 58, a first conductive bonding member 61, a second conductive bonding member 62, a first metal portion 63, a second metal portion 64, and a sealing resin 7.

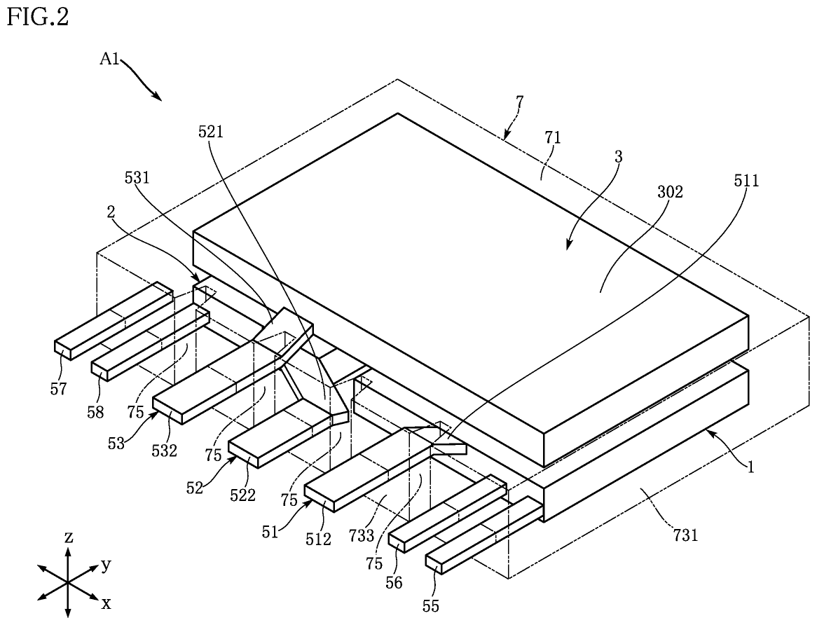

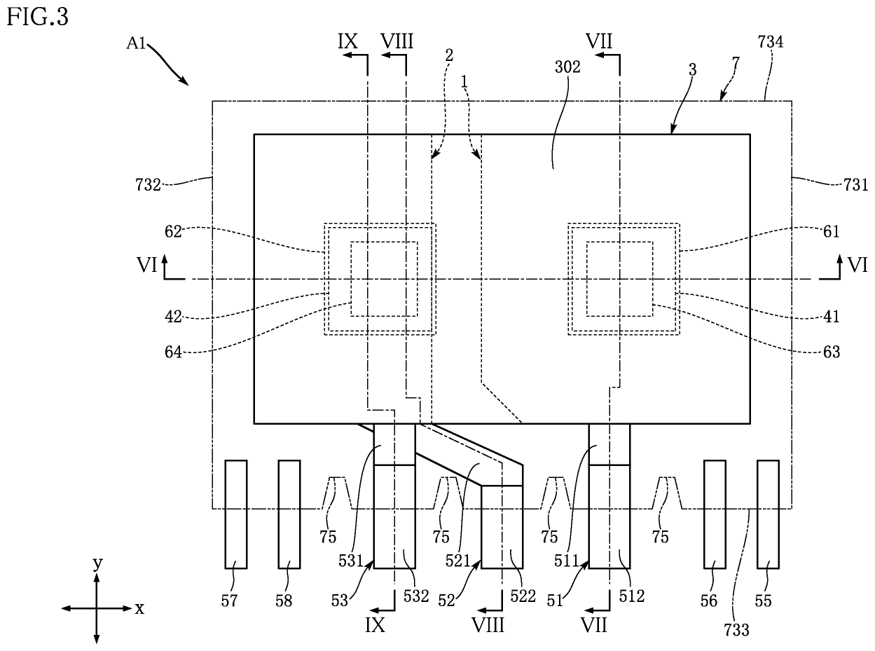

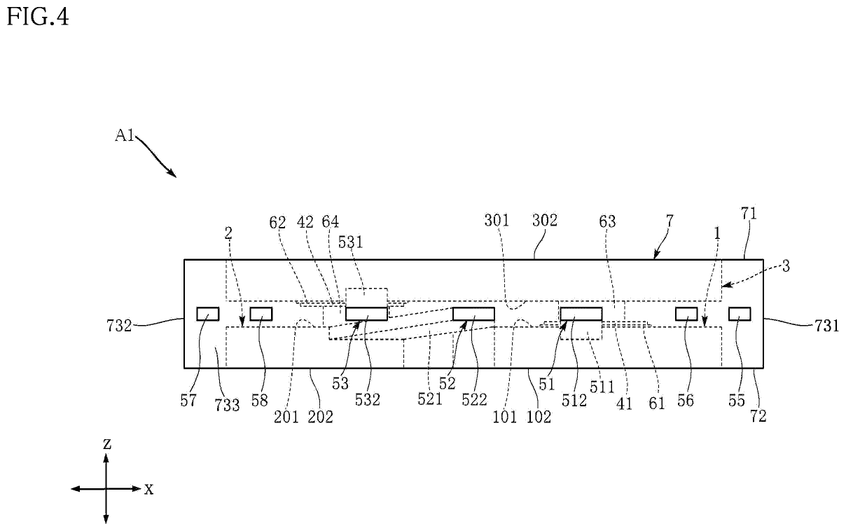

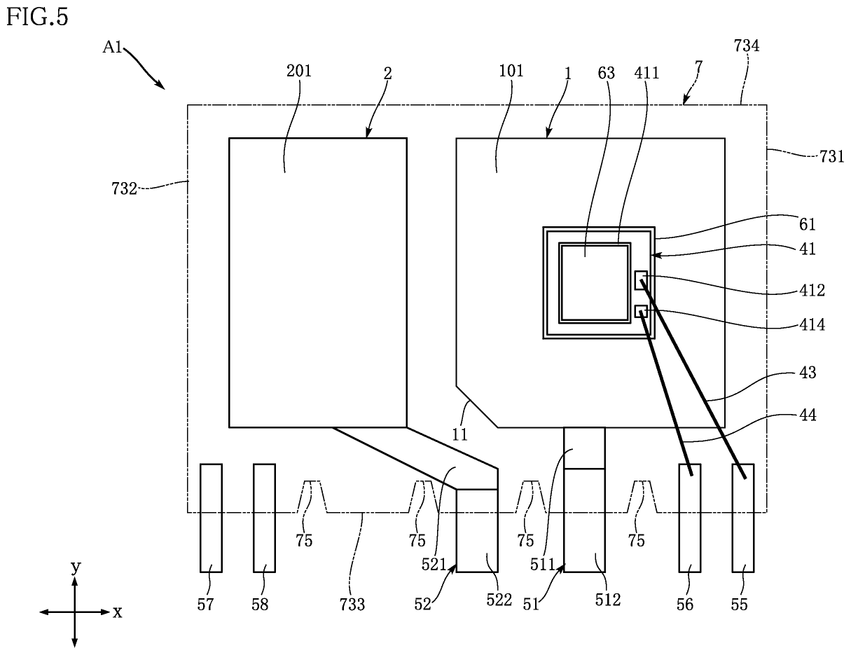

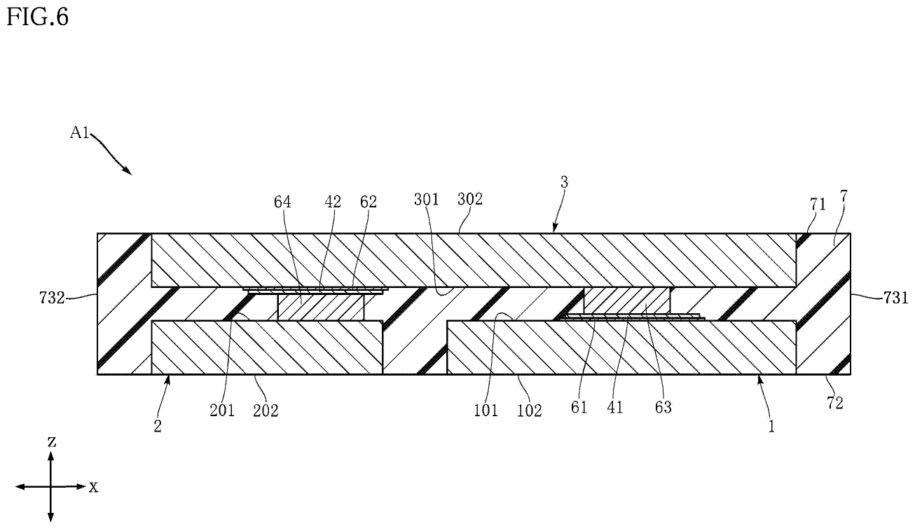

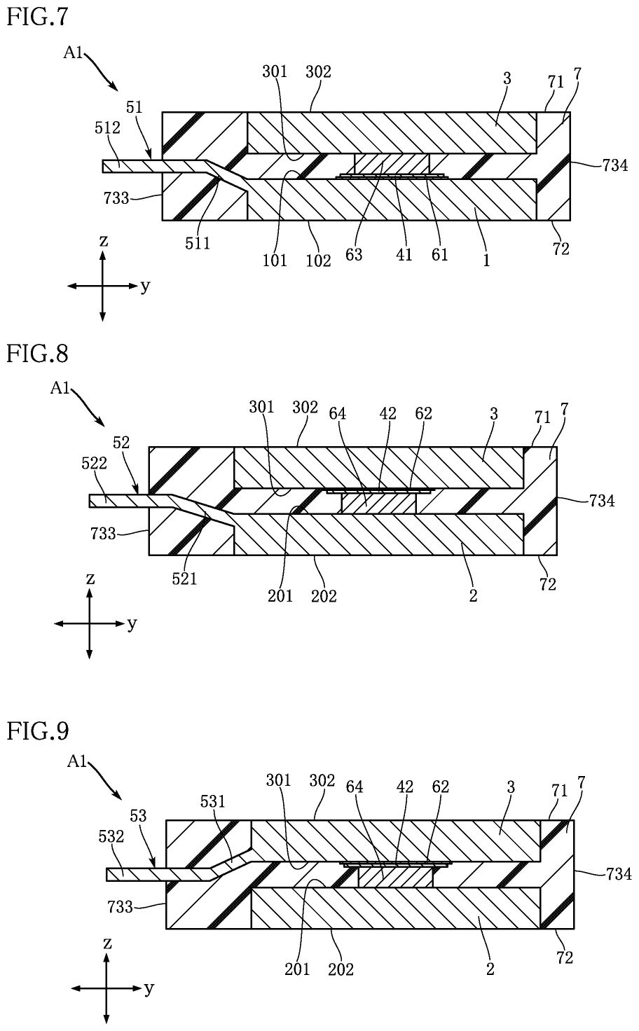

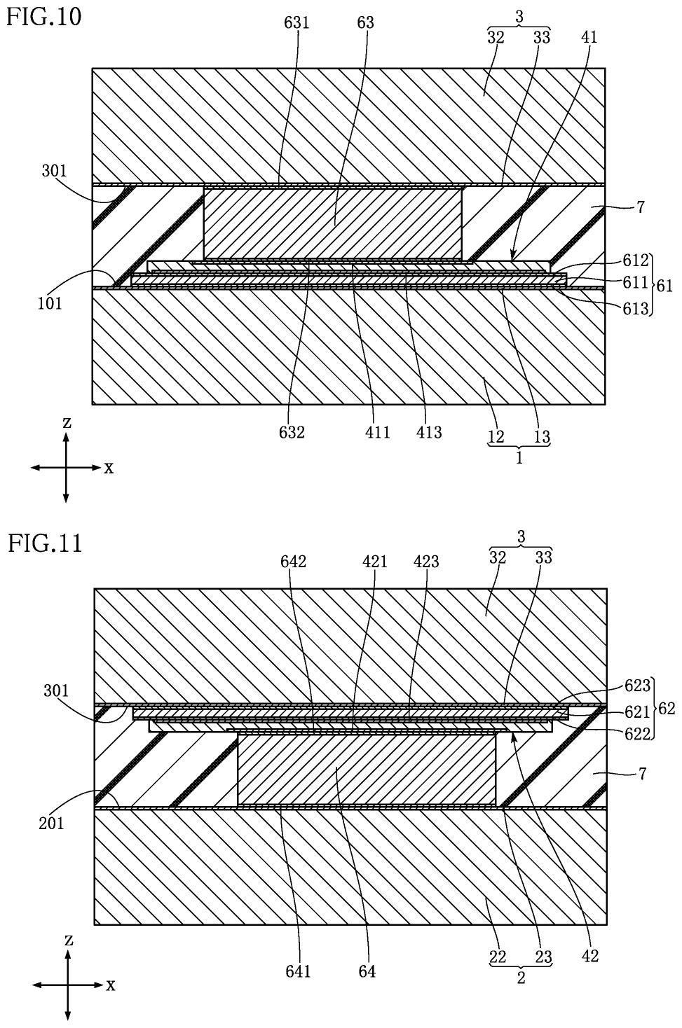

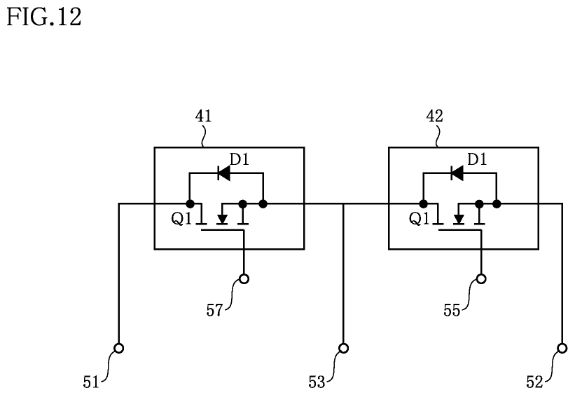

FIG. 1 is a perspective view showing the semiconductor device A1. FIG. 2 is a perspective view showing the semiconductor device A1. FIG. 3 is a plan view showing the semiconductor device A1. FIG. 4 is a front view showing the semiconductor device A1. FIG. 5 is a plan view showing the semiconductor device A1. FIG. 6 is a cross-sectional view taken along line VI-VI in FIG. 3. FIG. 7 is a cross-sectional view taken along line VII-VII in FIG. 3. FIG. 8 is a cross-sectional view taken along line VIII-VIII in FIG. 7. FIG. 9 is a cross-sectional view taken along line IX-IX in FIG. 3. FIGS. 10 and 11 are each a partially enlarged view of FIG. 6. FIG. 12 is an example of the circuit configuration of the semiconductor device according to the first embodiment. FIGS. 2, 3, and 5 each show the sealing resin 7 in phantom for convenience of understanding. FIG. 5 omits the third conductive plate 3 and the second semiconductor element 42.

In the description of the semiconductor device A1, the thickness direction of the first conductive plate 1 is referred to as “thickness direction z”. A direction perpendicular to the thickness direction z is referred to as “first direction x”. The direction perpendicular to both of the thickness direction z and the first direction x is referred to as “second direction y”.

In the present embodiment, each of the first conductive plate 1, the second conductive plate 2, and the third conductive plate 3 is formed by punching or bending a metal plate, for example. The constituent material of each of the first conductive plate 1, the second conductive plate 2, and the third conductive plate 3 is copper (Cu) or a copper alloy, for example. The thickness (the dimension in the thickness direction z) of each of the first conductive plate 1, the second conductive plate 2, and the third conductive plate 3 is not particularly limited, and may be about 0.1 mm to 2.5 mm, preferably about 2.0 mm.

The first conductive plate 1 is a member on which the first semiconductor element 41 is mounted. As shown in FIGS. 3 to 7, the first conductive plate 1 has a first obverse surface 101 and a first reverse surface 102. The first obverse surface 101 faces in a first sense of the thickness direction z, and the first reverse surface 102 faces in a second sense of the thickness direction z. The first semiconductor element 41 is mounted on the first obverse surface 101. The shape of the first conductive plate 1 is not particularly limited. In the illustrated example, the first conductive plate 1 has a chamfer 11, and has a rectangular (or substantially rectangular) shape with one corner cut off as viewed in the thickness direction z. As shown in FIGS. 6 and 7, in the present embodiment, the first reverse surface 102 is exposed from the sealing resin 7.

In the present embodiment, the first conductive plate 1 includes a base member 12 and an obverse-surface bonding layer 13, as shown in FIG. 10. The constituent material of the base member 12 is copper or a copper alloy. The obverse-surface bonding layer 13 overlaps with the base member 12 in the first sense of the thickness direction z. The obverse-surface bonding layer 13 is a silver (Ag) plating layer, for example. The surface of the obverse-surface bonding layer 13 facing in the first sense of the thickness direction z corresponds to the first obverse surface 101 of the first conductive plate 1.

As shown in FIG. 5, the second conductive plate 2 is spaced apart from the first conductive plate 1 in the first direction x, as viewed in the thickness direction z. In the illustrated example, the second conductive plate 2 is offset from the first conductive plate 1 in a second sense of the first direction x. As shown in FIGS. 3 to 6, 8, and 9, the second conductive plate 2 has a second obverse surface 201 and a second reverse surface 202. The second obverse surface 201 faces in the first sense of the thickness direction z, and the second reverse surface 202 faces in the second sense of the thickness direction z. The shape of the second conductive plate 2 is not particularly limited, but in the illustrated example, has a rectangular (or substantially rectangular) shape as viewed in the thickness direction z. As shown in FIGS. 6, 8, and 9, in the present embodiment, the second reverse surface 202 is exposed from the sealing resin 7.

In the present embodiment, the second conductive plate 2 includes a base member 22 and an obverse-surface bonding layer 23, as shown in FIG. 11. The constituent material of the base member 22 is copper or a copper alloy. The obverse-surface bonding layer 23 overlaps with the base member 22 in the first sense of the thickness direction z. The obverse-surface bonding layer 23 is a silver plating layer, for example. The surface of the obverse-surface bonding layer 23 facing in the first sense of the thickness direction z corresponds to the second obverse surface 201 of the second conductive plate 2.

As shown in FIG. 5, the dimension of the first conductive plate 1 in the first direction x is larger than the dimension of the second conductive plate 2 in the first direction x. The dimension of the first conductive plate 1 in the second direction y is the same as the dimension of the second conductive plate 2 in the second direction y. Thus, as viewed in the thickness direction z, the area of the first conductive plate 1 is larger than the area of the second conductive plate 2.

As shown in FIGS. 4, and 6 to 9, the third conductive plate 3 is spaced apart from the first conductive plate 1 and the second conductive plate 2 in the first sense of the thickness direction z. The third conductive plate 3 is a member on which the second semiconductor element 42 is mounted. As shown in FIGS. 3, 4, and 6 to 9, the third conductive plate 3 has a third obverse surface 301 and a third reverse surface 302. The third obverse surface 301 faces in the second sense of the thickness direction z, and the third reverse surface 302 faces in the first sense of the thickness direction z. The third obverse surface 301 faces both of the first obverse surface 101 of the first conductive plate 1 and the second obverse surface 201 of the second conductive plate 2. The shape of the third conductive plate 3 is not particularly limited, but in the illustrated example, has a rectangular (or substantially rectangular) shape as viewed in the thickness direction z. In the present embodiment, the third conductive plate 3 overlaps with the entirety of each of the first conductive plate 1 and the second conductive plate 2 as viewed in the thickness direction z. As shown in FIGS. 6 to 9, in the present embodiment, the third reverse surface 302 is exposed from the sealing resin 7.

In the present embodiment, the third conductive plate 3 includes a base member 32 and an obverse-surface bonding layer 33, as shown in FIGS. 10 and 11. The constituent material of the base member 32 is copper or a copper alloy. The obverse-surface bonding layer 33 overlaps with the base member 32 in the second sense of the thickness direction z. The obverse-surface bonding layer 33 is a silver plating layer, for example. The surface of the obverse-surface bonding layer 33 facing in the second sense of the thickness direction z corresponds to the third obverse surface 301 of the third conductive plate 3.

Each of the first semiconductor element 41 and the second semiconductor element 42 is an electronic component that forms the functional core of the semiconductor device A10. The first semiconductor element 41 and the second semiconductor element 42 are made of a semiconductor material mainly containing silicon carbide (SiC), for example. The semiconductor material is not limited to SiC, and may be silicon (Si), gallium nitride (GaN), or diamond (C). Each of the first semiconductor element 41 and the second semiconductor element 42 is a power semiconductor chip having a switching function unit Q1 (see FIG. 12) such as a metal oxide semiconductor field effect transistor (MOSFET), for example. The first semiconductor element 41 and the second semiconductor element 42 are MOSFETs in the present embodiment, but may be other transistors such as insulated gate bipolar transistors (IGBTs) in other examples.

As shown in FIG. 12, the semiconductor device A1 is configured as a half-bridge switching circuit, for example. In this case, the first semiconductor element 41 forms an upper arm circuit of the semiconductor device A1, and the second semiconductor element 42 forms a lower arm circuit of the semiconductor device A1. The first semiconductor element 41 and the second semiconductor element 42 are connected in series to form a bridge layer.

The first semiconductor element 41 is mounted on the first conductive plate 1 via the first conductive bonding member 61. As shown in FIGS. 6, 7, and 10, the first semiconductor element 41 is arranged between the first obverse surface 101 of the first conductive plate 1 and the third obverse surface 301 of the third conductive plate 3 in the thickness direction z.

As shown in FIGS. 5 and 10, the first semiconductor element 41 has a first source electrode 411, a first gate electrode 412, a first drain electrode 413, and a first source sense electrode 414. The first source electrode 411, the first gate electrode 412, and the first source sense electrode 414 are provided on the surface of the first semiconductor element 41 that faces in the first sense of the thickness direction z. These electrodes 411, 412, and 414 face in the first sense of the thickness direction z. The first drain electrode 413 is provided on the surface of the first semiconductor element 41 that faces in the second sense of the thickness direction z. The first drain electrode 413 faces in the second sense of the thickness direction z. A source current from within the first semiconductor element 41 flows through the first source electrode 411. A drive signal (e.g., gate voltage) for driving the first semiconductor element 41 is inputted to the first gate electrode 412. A drain current flows through the first drain electrode 413 to the inside of the first semiconductor element 41. The first drain electrode 413 is formed by Ag plating, for example. A source current flows through the first source sense electrode 414.

The second semiconductor element 42 is mounted on the third conductive plate 3 via the second conductive bonding member 62. As shown in FIGS. 6, 8, 9, and 11, the second semiconductor element 42 is arranged between the third obverse surface 301 of the third conductive plate 3 and the second obverse surface 201 of the second conductive plate 2 in the thickness direction z.

As shown in FIG. 11, the second semiconductor element 42 has a second source electrode 421, a second gate electrode (not shown), a second drain electrode 423, and a second source sense electrode (not shown). The second source electrode 421, the second gate electrode, and the second source sense electrode are provided on the surface of the second semiconductor element 42 that faces in the second sense of the thickness direction z, and face in the second sense of the thickness direction z. The second drain electrode 423 is provided on the surface of the second semiconductor element 42 that faces in the first sense of the thickness direction z, and faces in the first sense of the thickness direction z. The second semiconductor element 42 has substantially the same configuration as the first semiconductor element 41, but is arranged in an inverted posture in the thickness direction z. A source current from within the second semiconductor element 42 flows through the second source electrode 421. A drive signal (e.g., gate voltage) for driving the second semiconductor element 42 is inputted to the second gate electrode. A drain current flows through the second drain electrode 423 to the inside of the second semiconductor element 42. The second drain electrode 423 is formed by Ag plating, for example. A source current flows through the second source sense electrode.

The thickness (the dimension in the thickness direction z) of each of the first semiconductor element 41 and the second semiconductor element 42 is not particularly limited, and may be about 0.15 mm.

When a drive signal (gate voltage) is inputted to the first gate electrode 412 (the second gate electrode), the first semiconductor element 41 (the second semiconductor element 42) switches between a connected state and a disconnected state according to the drive signal via the switching function unit Q1. In the connected state, a current flows from the first drain electrode 413 (the second drain electrode 423) to the first source electrode 411 (the second source electrode 421), and in the disconnected state, the current does not flow. The switching function unit Q1 causes the first semiconductor element 41 and the second semiconductor element 42 to perform switching operations. The semiconductor device A1 converts the DC voltage inputted to the first input terminal 51 and the second input terminal 52 into an AC voltage, for example, via the switching function unit Q1 of each of the first semiconductor element 41 and the second semiconductor element 42, and outputs the AC voltage from the output terminal 53. Note that a diode Dl shown in FIG. 12 is, for example, a parasitic diode component of the switching function unit Q1.

Each of the first input terminal 51, the second input terminal 52, and the output terminal 53 is made of a metal plate. The constituent material of each of the first input terminal 51, the second input terminal 52, and the output terminal 53 is copper or a copper alloy, for example.

A DC voltage targeted for power conversion is inputted to each of the first input terminal 51 and the second input terminal 52. The first input terminal 51 is a positive electrode (P terminal). The second input terminal 52 is a negative electrode (N terminal). The output terminal 53 outputs the AC voltage obtained by the power conversion performed by the first semiconductor element 41 and the second semiconductor element 42.

The first input terminal 51 is electrically connected to the first conductive plate 1, and is arranged in a first sense of the second direction y relative to the first conductive plate 1, as shown in FIG. 5. As shown in FIG. 7, the first input terminal 51 is integrally formed with the first conductive plate 1 in the present embodiment. The first input terminal 51 has a first bent portion 511 and a first extending portion 512. As shown in FIGS. 5 and 7, the first bent portion 511 is connected to a portion of the first conductive plate 1 that is located at the center in the first direction x and at the end in the first sense of the thickness direction z. The first bent portion 511 is more offset in the first sense of the thickness direction z as it extends in the first sense of the second direction y. The first extending portion 512 is connected to a tip of the first bent portion 511 and extends in the first sense of the second direction y. A portion of the first extending portion 512 is exposed from the sealing resin 7.

The second input terminal 52 is electrically connected to the second conductive plate 2, and is arranged in the first sense of the second direction y relative to the second conductive plate 2, as shown in FIG. 5. As shown in FIG. 8, the second input terminal 52 is integrally formed with the second conductive plate 2 in the present embodiment. The second input terminal 52 has a second bent portion 521 and a second extending portion 522. As shown in FIGS. 5 and 8, the second bent portion 521 is connected to a portion of the second conductive plate 2 that is located at the end in a first sense of the first direction x and at the end in the first sense of the thickness direction z. The second bent portion 521 extends in the first sense of the second direction y and in the first sense of the first direction x, and is more offset in the first sense of the thickness direction z with the approach to a tip of the second bent portion 521. The second extending portion 522 is connected to the tip of the second bent portion 521 and extends in the first sense of the second direction y. A portion of the second extending portion 522 is exposed from the sealing resin 7.

The output terminal 53 is electrically connected to the third conductive plate 3, and is arranged in the first sense of the second direction y relative to the third conductive plate 3, as shown in FIG. 3. As shown in FIG. 9, the output terminal 53 is integrally formed with the third conductive plate 3 in the present embodiment. The output terminal 53 has a third bent portion 531 and a third extending portion 532. As shown in FIGS. 3 and 9, the third bent portion 531 is connected to a portion of the third conductive plate 3 that is offset in a second sense of the first direction x and at the end in the second sense of the thickness direction z. The third bent portion 531 is more offset in the second sense of the thickness direction z as it extends in the first sense of the second direction y. The third extending portion 532 is connected to a tip of the third bent portion 531 and extends in the first sense of the second direction y. A portion of the third extending portion 532 is exposed from the sealing resin 7.

In the present embodiment, as shown in FIGS. 4, and 7 to 9, the first extending portion 512 of the first input terminal 51, the second extending portion 522 of the second input terminal 52, and the third extending portion 532 of the output terminal 53 are at the same position in the thickness direction z and overlap with each other as viewed in the first direction x.

The first control terminal 55 and the first control terminal 56 are terminals for controlling the first semiconductor element 41. As shown in FIGS. 3 to 5, the first control terminals 55 and 56 are arranged in the first sense of the second direction y relative to the first conductive plate 1, and are spaced apart from each other in the first direction x. The first control terminals 55 and 56 extend in the first sense of the second direction y. A portion of each of the first control terminals 55 and 56 is exposed from the sealing resin 7.

As shown in FIG. 5, a wire 43 is bonded to the first control terminal 55 and the first gate electrode 412 of the first semiconductor element 41. The first gate electrode 412 and the first control terminal 55 are electrically connected to each other via the wire 43. A wire 44 is bonded to the first control terminal 56 and the first source sense electrode 414 of the first semiconductor element 41. The first source sense electrode 414 and the first control terminal 56 are electrically connected to each other via the wire 44.

The second control terminal 57 and the second control terminal 58 are terminals for controlling the second semiconductor element 42. As shown in FIGS. 3 to 5, the second control terminals 57 and 58 are arranged in the first sense of the second direction y relative to the second conductive plate 2, and are spaced apart from each other in the first direction x. The second control terminals 57 and 58 extend in the first sense of the second direction y. A portion of each of the second control terminals 57 and 58 is exposed from the sealing resin 7.

A wire, which is not shown, is bonded to the second control terminal 57 and the second gate electrode of the second semiconductor element 42, and the second control terminal 57 and the second gate electrode are electrically connected to each other via the wire. A wire, which is not shown, is bonded to the second control terminal 58 and the second source sense electrode of the second semiconductor element 42, and the second control terminal 58 and the second source sense electrode are electrically connected to each other via the wire.

In the present embodiment, as shown in FIG. 4, the first control terminals 55 and 56, and the second control terminals 57 and 58 are at the same position as the first extending portion 512, the second extending portion 522, and the third extending portion 532 in the thickness direction z. As a result, the first extending portion 512, the second extending portion 522, the third extending portion 532, the first control terminals 55 and 56, and the second control terminals 57 and 58 overlap with each other as viewed in the first direction x.

As shown in FIG. 10, the first conductive bonding member 61 is provided between the first conductive plate 1 and the first semiconductor element 41, and electrically connects and bonds the first obverse surface 101 and the first drain electrode 413. In the present embodiment, the first conductive bonding member 61 includes a first base layer 611, a first layer 612, and a second layer 613 that are stacked on each other.

The first base layer 611 is made of a metal such as aluminum (Al) or an aluminum alloy. The first base layer 611 is a sheet member, for example.

The first layer 612 is formed in the first sense of the thickness direction z relative to the first base layer 611. The first layer 612 is provided between the first base layer 611 and the first drain electrode 413. The first layer 612 is a silver plating layer, for example. The first layer 612 is bonded to the first drain electrode 413 of the first semiconductor element 41 by the solid-phase diffusion of metal, for example. In other words, the first layer 612 and the first drain electrode 413 are bonded by solid-phase diffusion, and are in direct contact with each other at the bonding interface.

The second layer 613 is formed in the second sense of the thickness direction z relative to the first base layer 611. The second layer 613 is provided between the first base layer 611 and the first conductive plate 1. The second layer 613 is a silver plating layer, for example. The second layer 613 is bonded to the obverse-surface bonding layer 13 of the first conductive plate 1 by the solid-phase diffusion of metal, for example. In other words, the second layer 613 and the obverse-surface bonding layer 13 are bonded by solid-phase diffusion, and are in direct contact with each other at the bonding interface. Bonding by the solid-phase diffusion of metal as described above may be performed under the following conditions: the heating temperature during the bonding process being in a range of about 200° C. to 350° C.; and the pressure applied during the bonding process being in the range of 1 MPa to 100 MPa. Solid-phase diffusion may take place either in the atmosphere or in a vacuum. Unlike the present embodiment, the first conductive bonding member 61 may be made of solder, and the first conductive bonding member 61 may be electrically connected and bonded to both of the first obverse surface 101 and the first drain electrode 413.

As shown in FIG. 11, the second conductive bonding member 62 is provided between the third conductive plate 3 and the second semiconductor element 42, and electrically connects and bonds the third obverse surface 301 and the second drain electrode 423. In the present embodiment, the second conductive bonding member 62 includes a second base layer 621, a third layer 622, and a fourth layer 623 that are stacked on each other.

The second base layer 621 is made of a metal such as aluminum or an aluminum alloy. The second base layer 621 is a sheet member, for example.

The third layer 622 is formed in the second sense of the thickness direction z relative to the second base layer 621. The third layer 622 is provided between the second base layer 621 and the second drain electrode 423. The third layer 622 is a silver plating layer, for example. The third layer 622 is bonded to the second drain electrode 423 of the second semiconductor element 42 by the solid-phase diffusion of metal, for example. In other words, the third layer 622 and the second drain electrode 423 are bonded by solid-phase diffusion, and are in direct contact with each other at the bonding interface.

The fourth layer 623 is formed in the first sense of the thickness direction z relative to the second base layer 621. The fourth layer 623 is provided between the second base layer 621 and the third conductive plate 3. The fourth layer 623 is a silver plating layer, for example. The fourth layer 623 is bonded to the obverse-surface bonding layer 33 of the third conductive plate 3 by the solid-phase diffusion of metal, for example. In other words, the fourth layer 623 and the obverse-surface bonding layer 33 are bonded by solid-phase diffusion, and are in direct contact with each other at the bonding interface. Bonding by the solid-phase diffusion of metal as described above may be performed under the following conditions: the heating temperature during the bonding process being in a range of about 200° C. to 350° C.; and the pressure applied during the bonding process being in the range of 1 MPa to 100 MPa. Solid-phase diffusion may take place either in the atmosphere or in a vacuum. Unlike the present embodiment, the second conductive bonding member 62 may be made of solder, and the second conductive bonding member 62 may be electrically connected and bonded to both of the third obverse surface 301 and the second drain electrode 423.

As shown in FIG. 10, the first metal portion 63 is provided between the first source electrode 411 of the first semiconductor element 41 and the third obverse surface 301 of the third conductive plate 3, and electrically connects the first source electrode 411 and the third obverse surface 301. In the present embodiment, a fifth layer 631 and a sixth layer 632 are formed on the first metal portion 63.

The first metal portion 63 is made of a metal such as aluminum, an aluminum alloy, copper, or a copper alloy. The thickness (dimension in the thickness direction z) of the first metal portion 63 is not particularly limited, and may be about 1 mm, for example.

The fifth layer 631 is formed in the first sense of the thickness direction z relative to the first metal portion 63. The fifth layer 631 is provided between the first metal portion 63 and the third conductive plate 3. The fifth layer 631 is a silver plating layer, for example. The fifth layer 631 is bonded to the obverse-surface bonding layer 33 of the third conductive plate 3 by the solid-phase diffusion of metal, for example. In other words, the fifth layer 631 and the obverse-surface bonding layer 33 are bonded by solid-phase diffusion, and are in direct contact with each other at the bonding interface.

The sixth layer 632 is formed in the second sense of the thickness direction z relative to the first metal portion 63.

The sixth layer 632 is provided between the first metal portion 63 and the first source electrode 411. The sixth layer 632 is a silver plating layer, for example. The sixth layer 632 is bonded to the first source electrode 411 by the solid-phase diffusion of metal, for example. In other words, the sixth layer 632 and the first source electrode 411 are bonded by solid-phase diffusion, and are in direct contact with each other at the bonding interface. Bonding by the solid-phase diffusion of metal as described above may be performed under the following conditions: the heating temperature during the bonding process being in a range of about 200° C. to 350° C.; and the pressure applied during the bonding process being in the range of 1 MPa to 100 MPa. Solid-phase diffusion may take place either in the atmosphere or in a vacuum. Unlike the present embodiment, the first metal portion 63 may be electrically connected and bonded to both of the first source electrode 411 and the third obverse surface 301 via solder, for example.

As shown in FIG. 11, the second metal portion 64 is provided between the second source electrode 421 of the second semiconductor element 42 and the second obverse surface 201 of the second conductive plate 2, and electrically connects the second source electrode 421 and the second obverse surface 201. In the present embodiment, a seventh layer 641 and an eighth layer 642 are formed on the second metal portion 64.

The second metal portion 64 is made of a metal such as aluminum, an aluminum alloy, copper, or a copper alloy. The thickness (dimension in the thickness direction z) of the second metal portion 64 is not particularly limited, and may be about 1 mm, for example.

The seventh layer 641 is formed in the second sense of the thickness direction z relative to the second metal portion 64. The seventh layer 641 is provided between the second metal portion 64 and the second conductive plate 2. The seventh layer 641 is a silver plating layer, for example. The seventh layer 641 is bonded to the obverse-surface bonding layer 23 of the second conductive plate 2 by the solid-phase diffusion of metal, for example. In other words, the seventh layer 641 and the obverse-surface bonding layer 23 are bonded by solid-phase diffusion, and are in direct contact with each other at the bonding interface.

The eighth layer 642 is formed in the first sense of the thickness direction z relative to the second metal portion 64. The eighth layer 642 is provided between the second metal portion 64 and the second source electrode 421. The eighth layer 642 is a silver plating layer, for example. The eighth layer 642 is bonded to the second source electrode 421 by the solid-phase diffusion of metal, for example. In other words, the eighth layer 642 and the second source electrode 421 are bonded by solid-phase diffusion, and are in direct contact with each other at the bonding interface. Bonding by the solid-phase diffusion of metal as described above may be performed under the following conditions: the heating temperature during the bonding process being in a range of about 200° C. to 350° C.; and the pressure applied during the bonding process being in the range of 1 MPa to 100 MPa. Solid-phase diffusion may take place either in the atmosphere or in a vacuum. Unlike the present embodiment, the second metal portion 64 may be electrically connected and bonded to both of the second source electrode 421 and the second obverse surface 201 via solder, for example.

As shown in FIGS. 2 to 4, and 6 to 9, the sealing resin 7 covers a portion of each of the first conductive plate 1, the second conductive plate 2, and the third conductive plate 3, a portion of each of the first input terminal 51, the second input terminal 52, the output terminal 53, the first control terminals 55 and 56, and the second control terminals 57 and 58, the first semiconductor element 41, and the second semiconductor element 42. The constituent material of the sealing resin 7 is a black epoxy resin, for example.

As shown in FIGS. 3 to 9, the sealing resin 7 has a resin obverse surface 71, a resin reverse surface 72, a resin first side surface 731, a resin second side surface 732, a resin third side surface 733, and a resin fourth side surface 734. The resin obverse surface 71 faces in the first sense of the thickness direction z. The resin reverse surface 72 faces the opposite side from the resin obverse surface 71 (i.e., the side in the second sense of the thickness direction z). As shown in FIGS. 6 to 9, the first reverse surface 102 of the first conductive plate 1 and the second reverse surface 202 of the second conductive plate 2 are exposed from the resin reverse surface 72. The third reverse surface 302 of the third conductive plate 3 is exposed from the resin obverse surface 71.

As shown in FIG. 6, the resin first side surface 731 is connected to the resin obverse surface 71 and the resin reverse surface 72, and faces in the first sense of the first direction x. The resin second side surface 732 is connected to the resin obverse surface 71 and the resin reverse surface 72, and faces in the second sense of the first direction x. The resin first side surface 731 and the resin second side surface 732 are spaced apart from each other in the first direction x.

As shown in FIGS. 3, 7 to 9, the resin third side surface 733 is connected to the resin obverse surface 71, the resin reverse surface 72, the resin first side surface 731, and the resin second side surface 732, and faces in the first sense of the second direction y. The resin fourth side surface 734 is connected to the resin obverse surface 71, the resin reverse surface 72, the resin first side surface 731, and the resin second side surface 732, and faces in a second sense of the second direction y. The resin third side surface 733 and the resin fourth side surface 734 are spaced apart from each other in the second direction y. A portion of each of the first input terminal 51, the second input terminal 52, and the output terminal 53 (the first extending portion 512, the second extending portion 522, and the third extending portion 532), and a portion of each of the first control terminals 55 and 56 and the second control terminals 57 and 58 protrude from the resin third side surface 733 in the first sense of the second direction y.

In the present embodiment, the resin third side surface 733 is formed with a plurality of recesses 75. Each of the recesses 75 is recessed from the resin third side surface 733 in the second sense of the second direction y, and is formed from the resin obverse surface 71 to the resin reverse surface 72 in the thickness direction z. In the first direction x, the recesses 75 are formed one each between the first input terminal 51 and the second input terminal 52, between the second input terminal 52 and the output terminal 53, between the first input terminal 51 and the first control terminal 56, and between the output terminal 53 and the second control terminal 58. Each of the recesses 75 is provided to increase the creepage distance between a pair of adjacent terminals in the first direction x.

The following describes advantages of the present embodiment.

The semiconductor device A1 includes the first conductive plate 1, the second conductive plate 2, the third conductive plate 3, the first semiconductor element 41, the second semiconductor element 42, the first input terminal 51, the second input terminal 52, and the output terminal 53. The first conductive plate 1 and the second conductive plate 2 are spaced apart from each other in the first direction x, and the third conductive plate 3 is spaced apart from the first conductive plate 1 and the second conductive plate 2 in the thickness direction z. The first semiconductor element 41 is arranged between the first obverse surface 101 of the first conductive plate 1 and the third obverse surface 301 of the third conductive plate 3. The second semiconductor element 42 is arranged between the third obverse surface 301 of the third conductive plate 3 and the second obverse surface 201 of the second conductive plate 2. The first input terminal 51 is a positive electrode, and is electrically connected to the first conductive plate 1. The second input terminal 52 is a negative electrode, and is electrically connected to the second conductive plate 2. The output terminal 53 is electrically connected to the third conductive plate 3. According to this configuration, the heat generated in the first semiconductor element 41 is mainly transferred to the first conductive plate 1. The second semiconductor element 42 is arranged in a posture inverted from the posture of the first semiconductor element 41 in the thickness direction z. The heat generated in the second semiconductor element 42 is mainly transferred to the third conductive plate 3. In this way, the heat generated in the first semiconductor element 41 and the second semiconductor element 42 can be dispersed and released to the first conductive plate 1 and the third conductive plate 3 that are spaced apart from each other in the thickness direction z. This improves the heat dissipation property of the semiconductor device A1. Furthermore, the configuration in which the first semiconductor element 41 and the second semiconductor element 42 are arranged in the mutually inverted postures in the thickness direction z can reduce the inductance caused by the current flowing through the semiconductor device A1.

As viewed in the thickness direction z, the area of the first conductive plate 1 is larger than the area of the second conductive plate 2. This configuration allows the heat generated in the first semiconductor element 41 to be released efficiently to the first conductive plate 1.

The semiconductor device A1 includes the first metal portion 63 and the second metal portion 64. The first metal portion 63 is provided between the first source electrode 411 of the first semiconductor element 41 and the third obverse surface 301 of the third conductive plate 3, and electrically connects the first source electrode 411 and the third obverse surface 301. The second metal portion 64 is provided between the second source electrode 421 of the second semiconductor element 42 and the second obverse surface 201 of the second conductive plate 2, and electrically connects the second source electrode 421 and the second obverse surface 201. According to this configuration, the heat generated in the first semiconductor element 41 is transferred to the third conductive plate 3 via the first metal portion 63. Furthermore, the heat generated in the second semiconductor element 42 is transferred to the second conductive plate 2 via the second metal portion 64. This makes it possible to release the heat generated in the first semiconductor element 41 and the second semiconductor element 42 more efficiently. This further improves the heat dissipation property of the semiconductor device A1.

The first reverse surface 102 of the first conductive plate 1, the second reverse surface 202 of the second conductive plate 2, and the third reverse surface 302 of the third conductive plate 3 are all exposed from the sealing resin 7. This is more preferable for improving the heat dissipation property of the semiconductor device A1.

The first extending portion 512 (first input terminal 51), the second extending portion 522 (second input terminal 52), and the third extending portion 532 (output terminal 53) are exposed from the sealing resin 7, and extend from the resin third side surface 733 in the first sense of the second direction y. The first extending portion 512, the second extending portion 522, and the third extending portion 532 overlap with each other as viewed in the first direction x, and are at the same position in the thickness direction z. Owing to this configuration, the semiconductor device A1 is easy to handle when it is mounted on a non-illustrated circuit board or the like.

The first conductive bonding member 61 is bonded to the first drain electrode 413 and the first conductive plate 1 by the solid-phase diffusion of metal, for example. The first conductive bonding member 61 (the first layer 612 and the second layer 613) is bonded to and in direct contact with the first drain electrode 413 and the first conductive plate 1 at the bonding interfaces. This configuration allows the heat generated in the first semiconductor element 41 to be released efficiently to the first conductive plate 1 via the first conductive bonding member 61. The second conductive bonding member 62 is bonded to the second drain electrode 423 and the third conductive plate 3 by the solid-phase diffusion of metal, for example. The second conductive bonding member 62 (the third layer 622 and the fourth layer 623) is bonded to and in direct contact with the second drain electrode 423 and the third conductive plate 3 at the bonding interfaces. This configuration allows the heat generated in the second semiconductor element 42 to be released efficiently to the third conductive plate 3 via the second conductive bonding member 62. Such a configuration with the first conductive bonding member 61 and the second conductive bonding member 62 is more preferable for improving the heat dissipation property of the semiconductor device A1.

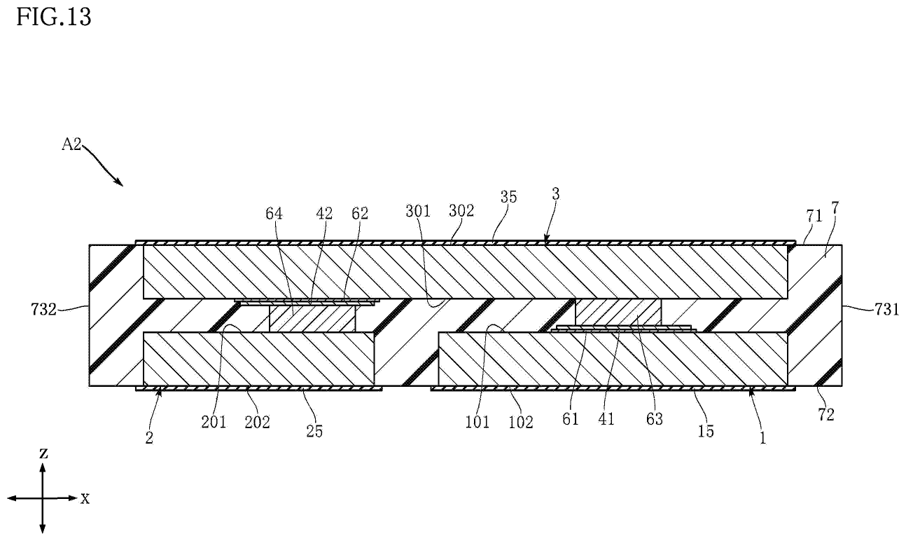

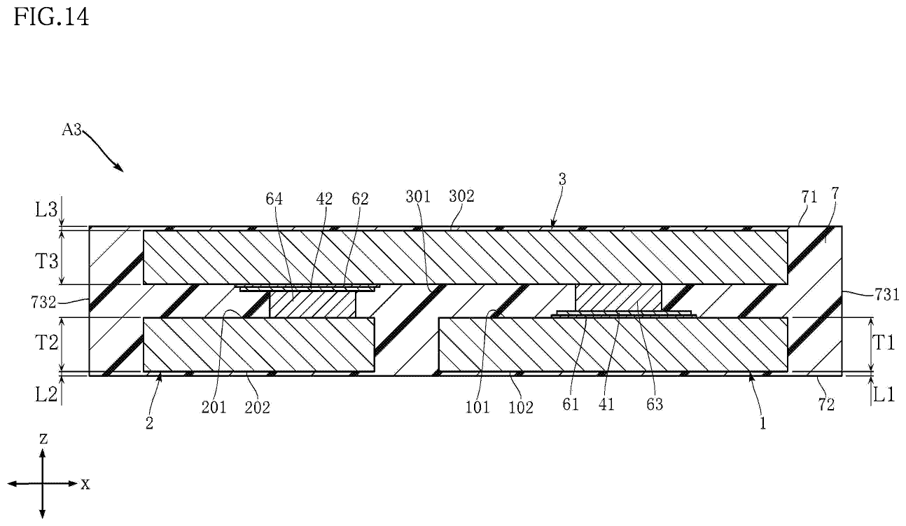

FIG. 13 shows a semiconductor device according to a second embodiment of the present disclosure. In FIG. 13 and the subsequent figures, the elements that are identical with or similar to those of the semiconductor device A1 in the above embodiment are designated by the same reference signs as in the above embodiment, and the descriptions thereof are omitted as appropriate.

A semiconductor device A2 in the present embodiment is different from the semiconductor device A1 in the above embodiment in further including an insulating layer 15, an insulating layer 25, and an insulating layer 35. The insulating layer 15 covers the first reverse surface 102 of the first conductive plate 1. The insulating layer 25 covers the second reverse surface 202 of the second conductive plate 2. The insulating layer 35 covers the third reverse surface 302 of the third conductive plate 3. Each of the insulating layers 15, 25, and 35 is not limited to a particular configuration, and may be made of a ceramic sheet or an insulating resin sheet.

In the semiconductor device A2, the first semiconductor element 41 is arranged between the first obverse surface 101 of the first conductive plate 1 and the third obverse surface 301 of the third conductive plate 3, and the second semiconductor element 42 is arranged between the third obverse surface 301 of the third conductive plate 3 and the second obverse surface 201 of the second conductive plate 2. The first input terminal 51 is a positive electrode, and is electrically connected to the first conductive plate 1. The second input terminal 52 is a negative electrode, and is electrically connected to the second conductive plate 2. The output terminal 53 is electrically connected to the third conductive plate 3. According to this configuration, the heat generated in the first semiconductor element 41 is mainly transferred to the first conductive plate 1. The second semiconductor element 42 is arranged in a posture inverted from the posture of the first semiconductor element 41 in the thickness direction z. The heat generated in the second semiconductor element 42 is mainly transferred to the third conductive plate 3. In this way, the heat generated in the first semiconductor element 41 and the second semiconductor element 42 can be dispersed and released to the first conductive plate 1 and the third conductive plate 3 that are spaced apart from each other in the thickness direction z. This improves the heat dissipation property of the semiconductor device A2.

The semiconductor device A2 includes the insulating layers 15, 25, and 35 that cover the first reverse surface 102, the second reverse surface 202, and the third reverse surface 302, respectively. This configuration ensures the electrical insulation of the semiconductor device A2 at both sides in the thickness direction z. Furthermore, the semiconductor device A2 has the same advantages as the semiconductor device A1 in the above embodiment within the range of the same configuration as that of the semiconductor device A1.

FIG. 14 shows a semiconductor device according to a third embodiment of the present disclosure. A semiconductor device A3 in the present embodiment is different from the semiconductor device A1 in the above embodiment in the configuration of the sealing resin 7.

Unlike the above embodiments, the sealing resin 7 of the semiconductor device A3 covers the first reverse surface 102, the second reverse surface 202, and the third reverse surface 302. A first dimension L1, which is the distance between the first reverse surface 102 and the resin reverse surface 72 in the thickness direction z, is smaller than a thickness T1 of the first conductive plate 1. A second dimension L2, which is the distance between the second reverse surface 202 and the resin reverse surface 72 in the thickness direction z, is smaller than a thickness T2 of the second conductive plate 2. A third dimension L3, which is the distance between the third reverse surface 302 and the resin obverse surface 71 in the thickness direction z, is smaller than a thickness T3 of the third conductive plate 3. Each of the first dimension L1, the second dimension L2, and the third dimension L3 is approximately 0.1 mm to 0.3 mm, for example.

The present embodiment is different from the above embodiments in the constituent material of the sealing resin 7. In the present embodiment, the sealing resin 7 has a predetermined thermal property and has a thermal conductivity of at least 5 W/mk. Examples of the constituent material of the sealing resin 7 include an epoxy resin containing fillers. The fillers may be made of aluminum oxide (Al₂O₃), boron nitride (BN), aluminum nitride (AlN), or silicon nitride (SiN), and the sealing resin 7 contains at least one of these listed compounds. The sealing resin 7 is a high thermal conductivity resin having a thermal conductivity of at least 5 W/mk, for example. With a thermal conductivity of at least 5 W/mk, the sealing resin 7 exhibits a better heat dissipation property than a general insulating sheet at the portions covering the first reverse surface 102, the second reverse surface 202, and the third reverse surface 302.

In the semiconductor device A3, the first semiconductor element 41 is arranged between the first obverse surface 101 of the first conductive plate 1 and the third obverse surface 301 of the third conductive plate 3, and the second semiconductor element 42 is arranged between the third obverse surface 301 of the third conductive plate 3 and the second obverse surface 201 of the second conductive plate 2. The first input terminal 51 is a positive electrode, and is electrically connected to the first conductive plate 1. The second input terminal 52 is a negative electrode, and is electrically connected to the second conductive plate 2. The output terminal 53 is electrically connected to the third conductive plate 3. According to this configuration, the heat generated in the first semiconductor element 41 is mainly transferred to the first conductive plate 1. The second semiconductor element 42 is arranged in a posture inverted from the posture of the first semiconductor element 41 in the thickness direction z. The heat generated in the second semiconductor element 42 is mainly transferred to the third conductive plate 3. In this way, the heat generated in the first semiconductor element 41 and the second semiconductor element 42 can be dispersed and released to the first conductive plate 1 and the third conductive plate 3 that are spaced apart from each other in the thickness direction z. This improves the heat dissipation property of the semiconductor device A3.

In the semiconductor device A3, the sealing resin 7 covers the first reverse surface 102, the second reverse surface 202, and the third reverse surface 302. This configuration ensures the electrical insulation of the semiconductor device A3 at both sides in the thickness direction z. The sealing resin 7 has a relatively high thermal conductivity, and the thickness (the first dimension L1, the second dimension L2, or the third dimension L3) of each of the portions of the sealing resin 7 that cover the first reverse surface 102, the second reverse surface 202, and the third reverse surface 302, respectively, is relatively small. This configuration can suppress a decrease in heat dissipation properties at the first reverse surface 102 of the first conductive plate 1, the second reverse surface 202 of the second conductive plate 2, and the third reverse surface 302 of the third conductive plate 3. Furthermore, the semiconductor device A3 has the same advantages as the semiconductor device A1 in the above embodiment within the range of the same configuration as that of the semiconductor device A1.

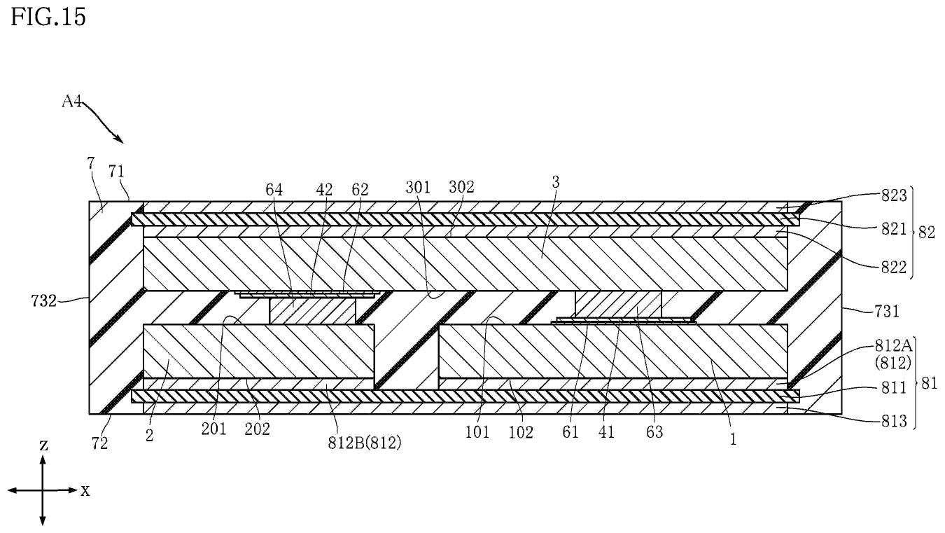

FIG. 15 shows a semiconductor device according to a fourth embodiment of the present disclosure. A semiconductor device A4 in the present embodiment is different from the semiconductor device A1 in the above embodiment in further including a first substrate 81 and a second substrate 82.

The first substrate 81 is arranged in the second sense of the thickness direction z relative to the first conductive plate 1 and the second conductive plate 2. The first substrate 81 includes a first insulating layer 811, a first metal layer 812, and a second metal layer 813. The first substrate 81 may be a direct bonded copper (DBC) substrate or an active metal brazing (AMB) substrate, for example. The first insulating layer 811 is made of ceramic having an excellent thermal conductivity, for example. Examples of such ceramic include aluminum nitride (AlN). As viewed in the thickness direction z, the first insulating layer 811 overlaps with the first reverse surface 102 (first conductive plate 1) and the second reverse surface 202 (second conductive plate 2).

The first metal layer 812 is formed in the first sense of the thickness direction z relative to the first insulating layer 811. The constituent material of the first metal layer 812 includes copper, for example. The first metal layer 812 includes a first portion 812A and a second portion 812B. The first portion 812A and the second portion 812B are spaced apart from each other in the first direction x. The first portion 812A is bonded to the first reverse surface 102 (first conductive plate 1). The second portion 812B is bonded to the second reverse surface 202 (second conductive plate 2). The second metal layer 813 is formed in the second sense of the thickness direction z relative to the first insulating layer 811. The second metal layer 813 is made of the same material as the first metal layer 812. In the illustrated example, the surface of the second metal layer 813 that faces in the second sense of the thickness direction z is exposed from the sealing resin 7.

The second substrate 82 is arranged in the second sense of the thickness direction z relative to the third conductive plate 3. The second substrate 82 includes a second insulating layer 821, a third metal layer 822, and a fourth metal layer 823. As with the first substrate 81, the second substrate 82 is a DBC substrate or an AMB substrate, for example. The second insulating layer 821, the third metal layer 822, and the fourth metal layer 823 are made of the same materials as the first insulating layer 811, the first metal layer 812, and the second metal layer 813 in the first substrate 81. As viewed in the thickness direction z, the second insulating layer 821 overlaps with the third reverse surface 302 (third conductive plate 3).

The third metal layer 822 is formed in the second sense of the thickness direction z relative to the second insulating layer 821. The third metal layer 822 is bonded to the third reverse surface 302 (third conductive plate 3). The fourth metal layer 823 is formed in the first sense of the thickness direction z relative to the second insulating layer 821. In the illustrated example, the surface of the fourth metal layer 823 that faces in the first sense of the thickness direction z is exposed from the sealing resin 7.

In the semiconductor device A4, the first semiconductor element 41 is arranged between the first obverse surface 101 of the first conductive plate 1 and the third obverse surface 301 of the third conductive plate 3, and the second semiconductor element 42 is arranged between the third obverse surface 301 of the third conductive plate 3 and the second obverse surface 201 of the second conductive plate 2. The first input terminal 51 is a positive electrode, and is electrically connected to the first conductive plate 1. The second input terminal 52 is a negative electrode, and is electrically connected to the second conductive plate 2. The output terminal 53 is electrically connected to the third conductive plate 3. According to this configuration, the heat generated in the first semiconductor element 41 is mainly transferred to the first conductive plate 1. The second semiconductor element 42 is arranged in a posture inverted from the posture of the first semiconductor element 41 in the thickness direction z. The heat generated in the second semiconductor element 42 is mainly transferred to the third conductive plate 3. In this way, the heat generated in the first semiconductor element 41 and the second semiconductor element 42 can be dispersed and released to the first conductive plate 1 and the third conductive plate 3 that are spaced apart from each other in the thickness direction z. This improves the heat dissipation property of the semiconductor device A4.

The semiconductor device A4 includes the first insulating layer 811 and the second insulating layer 821. The first insulating layer 811 is arranged in the second sense of the thickness direction z relative to the first reverse surface 102 and the second reverse surface 202, and overlaps with the first reverse surface 102 and the second reverse surface 202 as viewed in the thickness direction z. The second insulating layer 821 is arranged in the first sense of the thickness direction z relative to the third reverse surface 302, and overlaps with the third reverse surface 302 as viewed in the thickness direction z. This configuration ensures the electrical insulation of the semiconductor device A4 at both sides in the thickness direction z.

In the semiconductor device A4, the first insulating layer 811 and the second insulating layer 821 form a portion of the first substrate 81 and a portion of the second substrate 82, respectively (e.g., each of the first and second substrates 81 and 82 being either a DBC substrate or an AMB substrate). The first metal layer 812 of the first substrate 81 is bonded to the first conductive plate 1 and the second conductive plate 2, and the third metal layer 822 of the second substrate 82 is bonded to the third conductive plate 3. This configuration can release the heat from the first conductive plate 1, the second conductive plate 2, and the third conductive plate 3 to the first substrate 81 and the second substrate 82. This is preferable for improving the heat dissipation property of the semiconductor device A4. Furthermore, the semiconductor device A4 has the same advantages as the semiconductor device A1 in the above embodiment within the range of the same configuration as that of the semiconductor device A1.

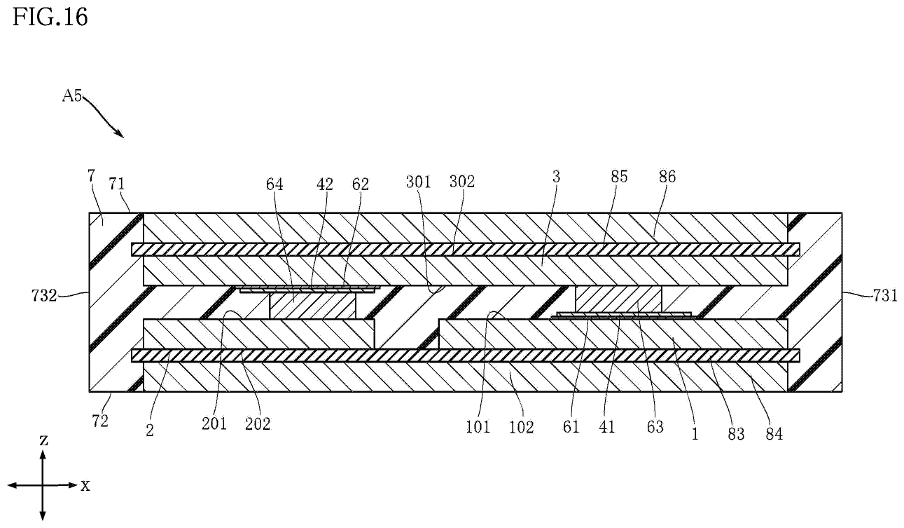

FIG. 16 shows a semiconductor device according to a fifth embodiment of the present disclosure. A semiconductor device A5 in the present embodiment is different from the semiconductor device A1 in the above embodiment in further including a first insulating layer 83, a conductive plate 84, a second insulating layer 85, and a conductive plate 86.

The first insulating layer 83 and the conductive plate 84 are arranged in the second sense of the thickness direction z relative to the first conductive plate 1 and the second conductive plate 2. In the present embodiment, the first conductive plate 1, the second conductive plate 2, the first insulating layer 83, and the conductive plate 84 constitute an AMB substrate, for example. The first conductive plate 1 and the second conductive plate 2 form a portion of the AMB substrate. The first insulating layer 83 is ceramic having an excellent thermal conductivity, for example. Examples of such ceramic include AlN. As viewed in the thickness direction z, the first insulating layer 83 overlaps with the first reverse surface 102 (first conductive plate 1) and the second reverse surface 202 (second conductive plate 2).

The first conductive plate 1 and the second conductive plate 2 are formed in the first sense of the thickness direction z relative to the first insulating layer 83. The constituent material of each of the first conductive plate 1 and the second conductive plate 2 includes copper, for example. The conductive plate 84 is formed in the second sense of the thickness direction z relative to the first insulating layer 83. The conductive plate 84 is made of the same material as the first conductive plate 1 and the second conductive plate 2. In the illustrated example, the surface of the conductive plate 84 that faces in the second sense of the thickness direction z is exposed from the sealing resin 7.

The second insulating layer 85 and the conductive plate 86 are arranged in the first sense of the thickness direction z relative to the third conductive plate 3. In the present embodiment, the third conductive plate 3, the second insulating layer 85, and the conductive plate 86 constitute an AMB substrate, for example. The third conductive plate 3 forms a portion of the AMB substrate. The third conductive plate 3 is made of the same material as the first conductive plate 1 and the second conductive plate 2. The second insulating layer 85 is made of the same material as the first insulating layer 83. The conductive plate 86 is made of the same material as the conductive plate 84. As viewed in the thickness direction z, the second insulating layer 85 overlaps with the third reverse surface 302 (third conductive plate 3).

The third conductive plate 3 is formed in the second sense of the thickness direction z relative to the second insulating layer 85. The conductive plate 86 is formed in the first sense of the thickness direction z relative to the second insulating layer 85. In the illustrated example, the surface of the conductive plate 86 that faces in the first sense of the thickness direction z is exposed from the sealing resin 7.

In the semiconductor device A5, the first semiconductor element 41 is arranged between the first obverse surface 101 of the first conductive plate 1 and the third obverse surface 301 of the third conductive plate 3, and the second semiconductor element 42 is arranged between the third obverse surface 301 of the third conductive plate 3 and the second obverse surface 201 of the second conductive plate 2. The first input terminal 51 is a positive electrode, and is electrically connected to the first conductive plate 1. The second input terminal 52 is a negative electrode, and is electrically connected to the second conductive plate 2. The output terminal 53 is electrically connected to the third conductive plate 3. According to this configuration, the heat generated in the first semiconductor element 41 is mainly transferred to the first conductive plate 1. The second semiconductor element 42 is arranged in a posture inverted from the posture of the first semiconductor element 41 in the thickness direction z. The heat generated in the second semiconductor element 42 is mainly transferred to the third conductive plate 3. In this way, the heat generated in the first semiconductor element 41 and the second semiconductor element 42 can be dispersed and released to the first conductive plate 1 and the third conductive plate 3 that are spaced apart from each other in the thickness direction z. This improves the heat dissipation property of the semiconductor device A5.

The semiconductor device A5 includes the first insulating layer 83 and the second insulating layer 85. The first insulating layer 83 is arranged in the second sense of the thickness direction z relative to the first reverse surface 102 and the second reverse surface 202, and overlaps with the first reverse surface 102 and the second reverse surface 202 as viewed in the thickness direction z. The second insulating layer 85 is arranged in the first sense of the thickness direction z relative to the third reverse surface 302, and overlaps with the third reverse surface 302 as viewed in the thickness direction z. This configuration ensures the electrical insulation of the semiconductor device A5 at both sides in the thickness direction z. Furthermore, the semiconductor device A5 has the same advantages as the semiconductor device A1 in the above embodiment within the range of the same configuration as that of the semiconductor device A1.

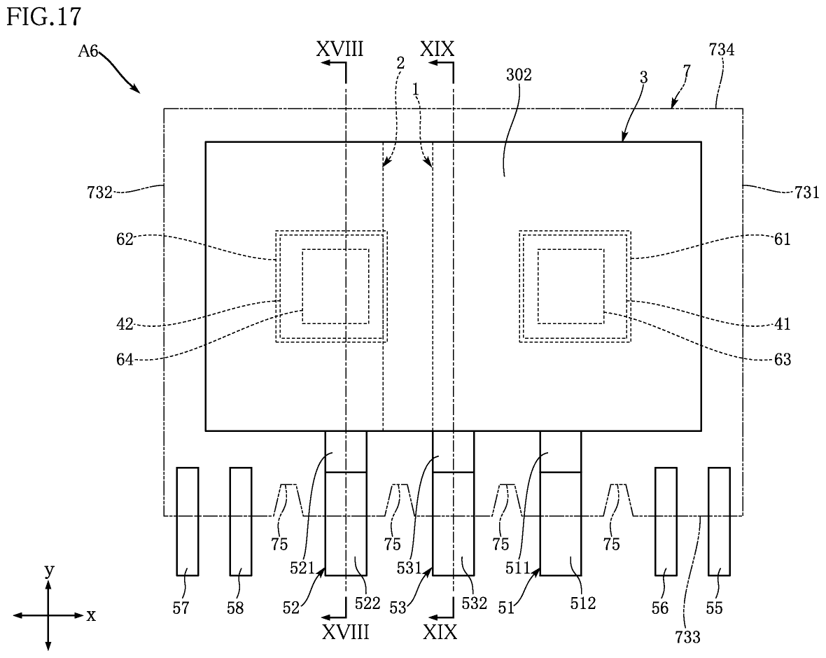

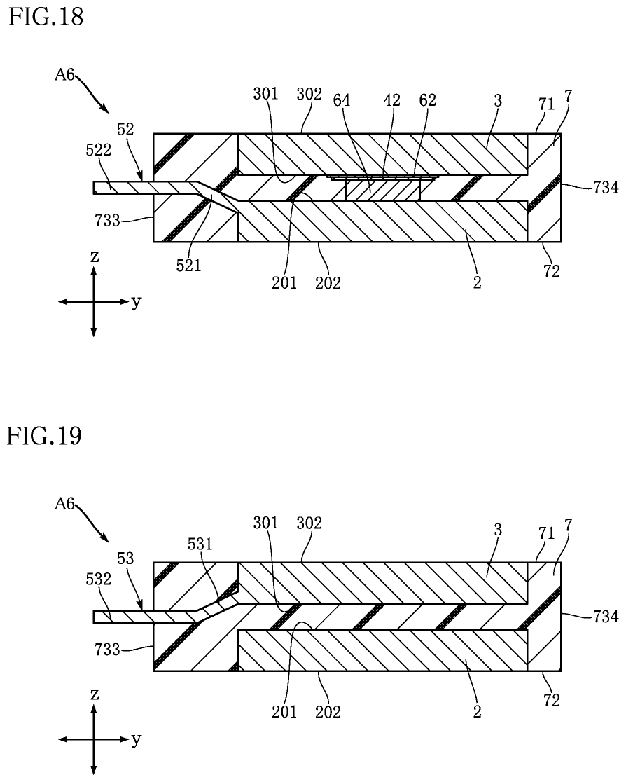

FIGS. 17 to 19 show a semiconductor device according to a sixth embodiment of the present disclosure. A semiconductor device A6 in the present embodiment is different from the semiconductor device A1 in the above embodiment in the arrangement of the second input terminal 52 and the output terminal 53.

In the semiconductor device A1 of the above embodiment, the output terminal 53 is arranged at the portion of the third conductive plate 3 that is offset in the second sense of the first direction x (see FIG. 3), whereas in the semiconductor device A6, the output terminal 53 is arranged at the center of the third conductive plate 3 in the first direction x. The second input terminal 52 is arranged in the second sense of the first direction x relative to the output terminal 53. In the semiconductor device A6, the second input terminal 52 and the output terminal 53 are switched around in position as compared to those in the semiconductor device A1.

In the semiconductor device A6, the first semiconductor element 41 is arranged between the first obverse surface 101 of the first conductive plate 1 and the third obverse surface 301 of the third conductive plate 3, and the second semiconductor element 42 is arranged between the third obverse surface 301 of the third conductive plate 3 and the second obverse surface 201 of the second conductive plate 2. The first input terminal 51 is a positive electrode, and is electrically connected to the first conductive plate 1. The second input terminal 52 is a negative electrode, and is electrically connected to the second conductive plate 2. The output terminal 53 is electrically connected to the third conductive plate 3. According to this configuration, the heat generated in the first semiconductor element 41 is mainly transferred to the first conductive plate 1. The second semiconductor element 42 is arranged in a posture inverted from the posture of the first semiconductor element 41 in the thickness direction z. The heat generated in the second semiconductor element 42 is mainly transferred to the third conductive plate 3. In this way, the heat generated in the first semiconductor element 41 and the second semiconductor element 42 can be dispersed and released to the first conductive plate 1 and the third conductive plate 3 that are spaced apart from each other in the thickness direction z. This improves the heat dissipation property of the semiconductor device A6.

The semiconductor device A6 is different from the semiconductor device A1 in the arrangement of the second input terminal 52 and the output terminal 53. The semiconductor device A6 can provide a variation of terminal arrangement different from that in the semiconductor device A1. Furthermore, the semiconductor device A6 has the same advantages as the semiconductor device A1 in the above embodiment within the range of the same configuration as that of the semiconductor device A1.

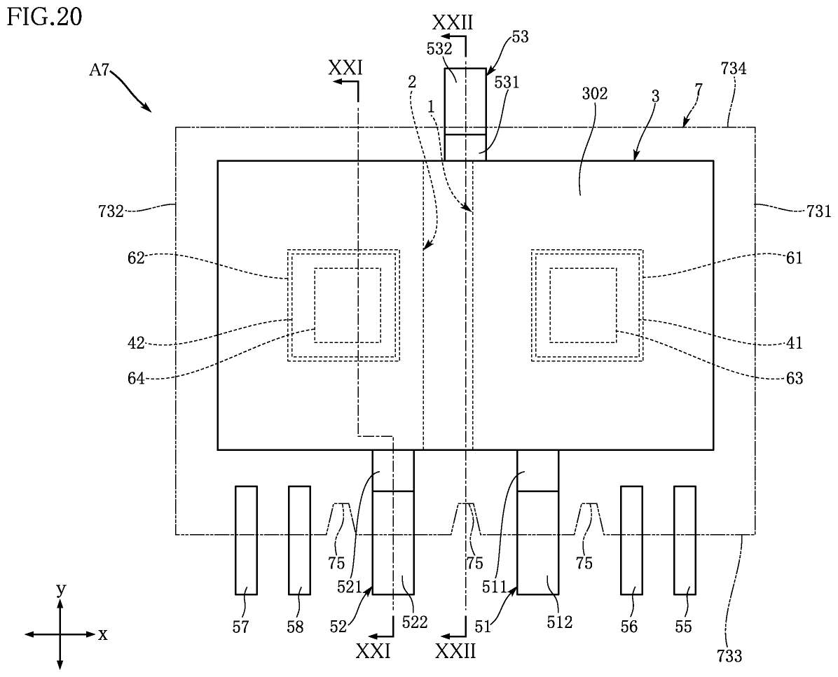

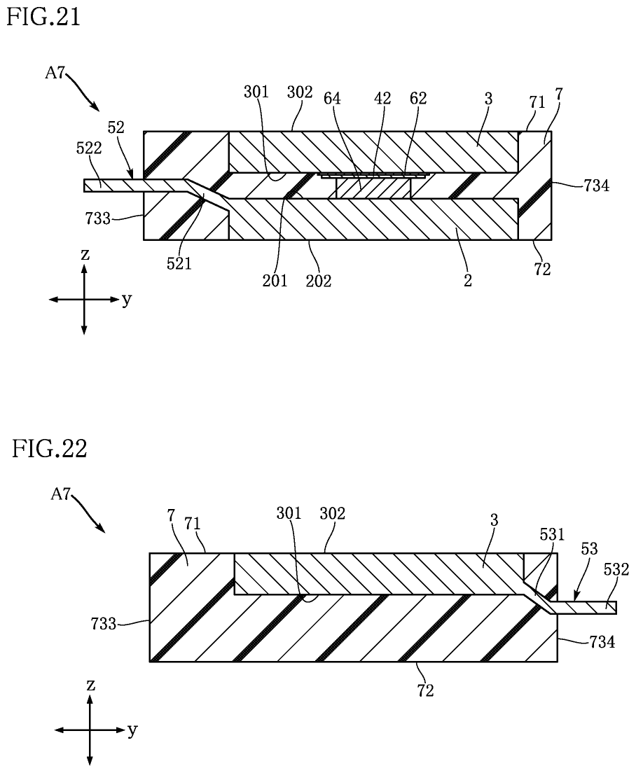

FIGS. 20 to 22 show a semiconductor device according to a seventh embodiment of the present disclosure. A semiconductor device A7 in the present embodiment is different from the semiconductor device A1 in the above embodiment mainly in the arrangement of the output terminal 53.

In the semiconductor device A1 of the above embodiment, the output terminal 53 is arranged in the first sense of the second direction y relative to the third conductive plate 3 (see FIG. 3), whereas in the semiconductor device A7, the output terminal 53 is arranged in the second sense of the second direction y relative to the third conductive plate 3. The output terminal 53 is arranged at the center of the third conductive plate 3 in the first direction x.

In the semiconductor device A7, the first semiconductor element 41 is arranged between the first obverse surface 101 of the first conductive plate 1 and the third obverse surface 301 of the third conductive plate 3, and the second semiconductor element 42 is arranged between the third obverse surface 301 of the third conductive plate 3 and the second obverse surface 201 of the second conductive plate 2. The first input terminal 51 is a positive electrode, and is electrically connected to the first conductive plate 1. The second input terminal 52 is a negative electrode, and is electrically connected to the second conductive plate 2. The output terminal 53 is electrically connected to the third conductive plate 3. According to this configuration, the heat generated in the first semiconductor element 41 is mainly transferred to the first conductive plate 1. The second semiconductor element 42 is arranged in a posture inverted from the posture of the first semiconductor element 41 in the thickness direction z. The heat generated in the second semiconductor element 42 is mainly transferred to the third conductive plate 3. In this way, the heat generated in the first semiconductor element 41 and the second semiconductor element 42 can be dispersed and released to the first conductive plate 1 and the third conductive plate 3 that are spaced apart from each other in the thickness direction z. This improves the heat dissipation property of the semiconductor device A7.

In the semiconductor device A7, the output terminal 53 is arranged opposite to the first input terminal 51 and the second input terminal 52 with respect to the third conductive plate 3, as viewed in the thickness direction z. This configuration increases the degree of freedom in the arrangement of the terminals. Furthermore, the semiconductor device A7 has the same advantages as the semiconductor device A1 in the above embodiment within the range of the same configuration as that of the semiconductor device A1.

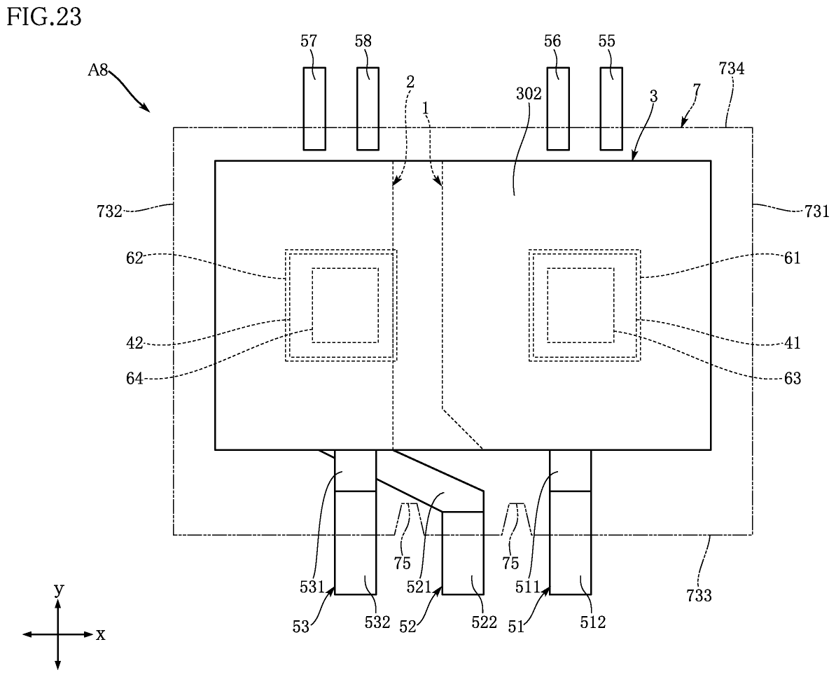

FIG. 23 shows a semiconductor device according to an eighth embodiment of the present disclosure. A semiconductor device A8 in the present embodiment is different from the semiconductor device A1 in the above embodiment mainly in the arrangement of the first control terminals 55 and 56 and the second control terminals 57 and 58.

In the semiconductor device A1 of the above embodiment, the first control terminals 55 and 56 and the second control terminals 57 and 58 are arranged in the first sense of the second direction y relative to the third conductive plate 3 (see FIG. 3), whereas in the semiconductor device A8, the first control terminals 55 and 56 and the second control terminals 57 and 58 are arranged in the second sense of the second direction y relative to the third conductive plate 3.

In the semiconductor device A8, the first semiconductor element 41 is arranged between the first obverse surface 101 of the first conductive plate 1 and the third obverse surface 301 of the third conductive plate 3, and the second semiconductor element 42 is arranged between the third obverse surface 301 of the third conductive plate 3 and the second obverse surface 201 of the second conductive plate 2. The first input terminal 51 is a positive electrode, and is electrically connected to the first conductive plate 1. The second input terminal 52 is a negative electrode, and is electrically connected to the second conductive plate 2. The output terminal 53 is electrically connected to the third conductive plate 3. According to this configuration, the heat generated in the first semiconductor element 41 is mainly transferred to the first conductive plate 1. The second semiconductor element 42 is arranged in a posture inverted from the posture of the first semiconductor element 41 in the thickness direction z. The heat generated in the second semiconductor element 42 is mainly transferred to the third conductive plate 3. In this way, the heat generated in the first semiconductor element 41 and the second semiconductor element 42 can be dispersed and released to the first conductive plate 1 and the third conductive plate 3 that are spaced apart from each other in the thickness direction z. This improves the heat dissipation property of the semiconductor device A8.

In the semiconductor device A8, the first control terminals 55 and 56 and the second control terminals 57 and 58 are arranged opposite to the first input terminal 51, the second input terminal 52, and the output terminal 53 with respect to the third conductive plate 3, as viewed in the thickness direction z. This configuration can suppress the effect of noise from the first input terminal 51, the second input terminal 52, and the output terminal 53 to the first control terminals 55 and 56 and the second control terminals 57 and 58. Furthermore, the semiconductor device A8 has the same advantages as the semiconductor device A1 in the above embodiment within the range of the same configuration as that of the semiconductor device A1.

The semiconductor device according to the present disclosure is not limited to the foregoing embodiments. Various design changes can be made to the specific configurations of the elements of the semiconductor device according to the present disclosure.

The present disclosure includes embodiments described in the following clauses.

Clause 1.

A semiconductor device comprising:
a first conductive plate including a first obverse surface facing in a first sense of a thickness direction and a first reverse surface facing in a second sense of the thickness direction;
a second conductive plate including a second obverse surface facing in the first sense of the thickness direction and a second reverse surface facing in the second sense of the thickness direction, the second conductive plate being spaced apart from the first conductive plate in a first direction perpendicular to the thickness direction;
a third conductive plate including a third obverse surface and a third reverse surface, the third obverse surface facing in the second sense of the thickness direction and facing the first obverse surface and the second obverse surface, the third reverse surface facing in the first sense of the thickness direction, the third conductive plate being spaced apart from the first conductive plate and the second conductive plate in the first sense of the thickness direction;
a first semiconductor element arranged between the first obverse surface and the third obverse surface in the thickness direction, and having a switching function;
a second semiconductor element arranged between the second obverse surface and the third obverse surface in the thickness direction, and having a switching function;
a first input terminal that is a positive electrode and is electrically connected to the first conductive plate;
a second input terminal that is a negative electrode and is electrically connected to the second conductive plate;
an output terminal electrically connected to the third conductive plate; and
a sealing resin that covers at least a portion of each of the first conductive plate, the second conductive plate, and the third conductive plate, that covers a portion of each of the first input terminal, the second input terminal, and the output terminal, and that covers the first semiconductor element and the second semiconductor element.

Clause 2.

The semiconductor device according to clause 1, wherein as viewed in the thickness direction, an area of the first conductive plate is larger than an area of the second conductive plate.

Clause 3.

The semiconductor device according to clause 1 or 2, wherein the first reverse surface, the second reverse surface, and the third reverse surface are exposed from the sealing resin.

Clause 4.

The semiconductor device according to clause 3, further comprising an insulating layer covering each of the first reverse surface, the second reverse surface, and the third reverse surface.

Clause 5.

The semiconductor device according to clause 1 or 2, wherein the first reverse surface, the second reverse surface, and the third reverse surface are covered with the sealing resin, and
the sealing resin has a thermal conductivity of at least 5 W/mk.

Clause 6.

The semiconductor device according to clause 5, wherein the sealing resin has a resin obverse surface facing in the first sense of the thickness direction and a resin reverse surface facing in the second sense of the thickness direction,
a first dimension between the first reverse surface and the resin reverse surface in the thickness direction is smaller than a thickness of the first conductive plate,
a second dimension between the second reverse surface and the resin reverse surface in the thickness direction is smaller than a thickness of the second conductive plate, and
a third dimension between the third reverse surface and the resin obverse surface in the thickness direction is smaller than a thickness of the third conductive plate.

Clause 7.

The semiconductor device according to clause 1 or 2, further comprising: a first insulating layer that is arranged in the second sense of the thickness direction relative to the first reverse surface, and that overlaps with the first reverse surface and the second reverse surface as viewed in the thickness direction; and
a second insulating layer that is arranged in the first sense of the thickness direction relative to the third reverse surface, and that overlaps with the third reverse surface as viewed in the thickness direction.

Clause 8.

The semiconductor device according to any of clauses 1 to 7, wherein the first input terminal has a first extending portion that is exposed from the sealing resin, and that extends in a second direction perpendicular to the thickness direction and the first direction,
the second input terminal has a second extending portion that is exposed from the sealing resin, and that extends in the second direction, and
the output terminal has a third extending portion that is exposed from the sealing resin, and that extends in the second direction.

Clause 9.

The semiconductor device according to clause 8, wherein the first extending portion is positioned in a first sense of the second direction relative to the first conductive plate, and extends in the first sense of the second direction,
the second extending portion is positioned in the first sense of the second direction relative to the second conductive plate, and extends in the first sense of the second direction, and
the third extending portion is positioned in the first sense of the second direction relative to the third conductive plate, and extends in the first sense of the second direction.

Clause 10.

The semiconductor device according to clause 9, wherein the first extending portion, the second extending portion, and the third extending portion overlap with each other as viewed in the first direction.

Clause 11.

The semiconductor device according to any of clauses 8 to 10, further comprising a first control terminal and a second control terminal for controlling the first semiconductor element and the second semiconductor element, respectively,
wherein the sealing resin covers a portion of each of the first control terminal and the second control terminal.

Clause 12.

The semiconductor device according to clause 11, wherein the first control terminal is spaced apart from the first conductive plate in the second direction, and extends in the second direction, and
the second control terminal is spaced apart from the third conductive plate in the second direction, and extends in the second direction.

Clause 13.

The semiconductor device according to any of clauses 1 to 12, further comprising a first conductive bonding member and a second conductive bonding member,
wherein the first semiconductor element has a first source electrode facing in the first sense of the thickness direction, and a first drain electrode facing in the second sense of the thickness direction,
the second semiconductor element has a second source electrode facing in the second sense of the thickness direction, and a second drain electrode facing in the first sense of the thickness direction,
the first conductive bonding member electrically connects and bonds the first obverse surface and the first drain electrode, and
the second conductive bonding member electrically connects and bonds the third obverse surface and the second drain electrode.

Clause 14.

The semiconductor device according to clause 13, further comprising: a first metal portion provided between the first source electrode and the third obverse surface, and electrically connects the first source electrode and the third obverse surface; and
a second metal portion provided between the second source electrode and the second obverse surface, and electrically connects the second source electrode and the second obverse surface.

Clause 15.

The semiconductor device according to clause 13 or 14, wherein the first conductive bonding member includes a first base layer made of metal, a first layer, and a second layer, the first layer being provided between the first base layer and the first drain electrode and bonded in direct contact with the first drain electrode at a bonding interface between the first layer and the first drain electrode, the second layer being provided between the first base layer and the first conductive plate and bonded in direct contact with the first conductive plate at a bonding interface between the second layer and the first conductive plate, and
the second conductive bonding member includes a second base layer made of metal, a third layer, and a fourth layer, the third layer being provided between the second base layer and the second drain electrode and bonded in direct contact with the second drain electrode at a bonding interface between the third layer and the second drain electrode, the fourth layer being provided between the second base layer and the third conductive plate and bonded in direct contact with the third conductive plate at a bonding interface between the fourth layer and the third conductive plate.

Clause 16.

The semiconductor device according to clause 15, wherein each of the first base layer and the second base layer contains aluminum, and
each of the first layer, the second layer, the third layer, and the fourth layer contains silver.

Clause 17.

The semiconductor device according to any of clauses 1 to 16, wherein each of the first conductive plate, the second conductive plate, and the third conductive plate contains copper.

### REFERENCE NUMERALS

A1, A2, A3, A4, A5, A6, A7, A8: Semiconductor device
1: First conductive plate 101: First obverse surface
102: First reverse surface
11: Chamfer 12: Base member
13: Obverse-surface bonding layer
15: Insulating layer 2: Second conductive plate
201: Second obverse surface
202: Second reverse surface 22: Base member
23: Obverse-surface bonding layer
25: Insulating layer 3: Third conductive plate
301: Third obverse surface
302: Third reverse surface 32: Base member
33: Obverse-surface bonding layer
35: Insulating layer 41: First semiconductor element
411: First source electrode
412: First gate electrode 413: First drain electrode
414: First source sense electrode
42: Second semiconductor element
421: Second source electrode 423: Second drain electrode
43, 44: Wire 51: First input terminal
511: First bent portion
512: First extending portion 52: Second input terminal
521: Second bent portion
522: Second extending portion 53: Output terminal
531: Third bent portion
532: Third extending portion 55, 56: First control terminal
57, 58: Second control terminal
61: First conductive bonding member
611: First base layer 612: First layer 613: Second layer
62: Second conductive bonding member 621: Second base layer
622: Third layer
623: Fourth layer 63: First metal portion 631: Fifth layer
632: Sixth layer 64: Second metal portion
641: Seventh layer
642: Eighth layer 7: Sealing resin
71: Resin obverse surface
72: Resin reverse surface 731: Resin first side surface
732: Resin second side surface
733: Resin third side surface 734: Resin fourth side surface
75: Recess
81: First substrate 811: First insulating layer
812: First metal layer
812A: First portion 812B: Second portion
813: Second metal layer
82: Second substrate 821: Second insulating layer
822: Third metal layer
823: Fourth metal layer 83: First insulating layer
84: Conductive plate
85: Second insulating layer 86: Conductive plate Dl: Diode
L1: First dimension L2: Second dimension
L3: Third dimension
Q1: Switching function unit
T1: Thickness (first conductive plate)
T2: Thickness (second conductive plate)
T3: Thickness (third conductive plate)
x: First direction y: Second direction
z: Thickness direction

1. A semiconductor device comprising:
a first conductive plate including a first obverse surface facing in a first sense of a thickness direction and a first reverse surface facing in a second sense of the thickness direction;
a second conductive plate including a second obverse surface facing in the first sense of the thickness direction and a second reverse surface facing in the second sense of the thickness direction, the second conductive plate being spaced apart from the first conductive plate in a first direction perpendicular to the thickness direction;
a third conductive plate including a third obverse surface and a third reverse surface, the third obverse surface facing in the second sense of the thickness direction and facing the first obverse surface and the second obverse surface, the third reverse surface facing in the first sense of the thickness direction, the third conductive plate being spaced apart from the first conductive plate and the second conductive plate in the first sense of the thickness direction;
a first semiconductor element arranged between the first obverse surface and the third obverse surface in the thickness direction, and having a switching function;
a second semiconductor element arranged between the second obverse surface and the third obverse surface in the thickness direction, and having a switching function;
a first input terminal that is a positive electrode and is electrically connected to the first conductive plate;
a second input terminal that is a negative electrode and is electrically connected to the second conductive plate;
an output terminal electrically connected to the third conductive plate; and
a sealing resin that covers at least a portion of each of the first conductive plate, the second conductive plate, and the third conductive plate, that covers a portion of each of the first input terminal, the second input terminal, and the output terminal, and that covers the first semiconductor element and the second semiconductor element.

2. The semiconductor device according to claim 1, wherein as viewed in the thickness direction, an area of the first conductive plate is larger than an area of the second conductive plate.

3. The semiconductor device according to claim 1, wherein the first reverse surface, the second reverse surface, and the third reverse surface are exposed from the sealing resin.

4. The semiconductor device according to claim 3, further comprising an insulating layer covering each of the first reverse surface, the second reverse surface, and the third reverse surface.

5. The semiconductor device according to claim 1, wherein the first reverse surface, the second reverse surface, and the third reverse surface are covered with the sealing resin, and
the sealing resin has a thermal conductivity of at least 5 W/mk.

6. The semiconductor device according to claim 5, wherein the sealing resin has a resin obverse surface facing in the first sense of the thickness direction and a resin reverse surface facing in the second sense of the thickness direction,
a first dimension between the first reverse surface and the resin reverse surface in the thickness direction is smaller than a thickness of the first conductive plate,
a second dimension between the second reverse surface and the resin reverse surface in the thickness direction is smaller than a thickness of the second conductive plate, and
a third dimension between the third reverse surface and the resin obverse surface in the thickness direction is smaller than a thickness of the third conductive plate.

7. The semiconductor device according to claim 1, further comprising: a first insulating layer that is arranged in the second sense of the thickness direction relative to the first reverse surface, and that overlaps with the first reverse surface and the second reverse surface as viewed in the thickness direction; and
a second insulating layer that is arranged in the first sense of the thickness direction relative to the third reverse surface, and that overlaps with the third reverse surface as viewed in the thickness direction.

8. The semiconductor device according to claim 1, wherein the first input terminal has a first extending portion that is exposed from the sealing resin, and that extends in a second direction perpendicular to the thickness direction and the first direction,
the second input terminal has a second extending portion that is exposed from the sealing resin, and that extends in the second direction, and
the output terminal has a third extending portion that is exposed from the sealing resin, and that extends in the second direction.

9. The semiconductor device according to claim 8, wherein the first extending portion is positioned in a first sense of the second direction relative to the first conductive plate, and extends in the first sense of the second direction,
the second extending portion is positioned in the first sense of the second direction relative to the second conductive plate, and extends in the first sense of the second direction, and
the third extending portion is positioned in the first sense of the second direction relative to the third conductive plate, and extends in the first sense of the second direction.

10. The semiconductor device according to claim 9, wherein the first extending portion, the second extending portion, and the third extending portion overlap with each other as viewed in the first direction.

11. The semiconductor device according to claim 8, further comprising a first control terminal and a second control terminal for controlling the first semiconductor element and the second semiconductor element, respectively,
wherein the sealing resin covers a portion of each of the first control terminal and the second control terminal.

12. The semiconductor device according to claim 11, wherein the first control terminal is spaced apart from the first conductive plate in the second direction, and extends in the second direction, and
the second control terminal is spaced apart from the third conductive plate in the second direction, and extends in the second direction.

13. The semiconductor device according to claim 1, further comprising a first conductive bonding member and a second conductive bonding member,
wherein the first semiconductor element has a first source electrode facing in the first sense of the thickness direction, and a first drain electrode facing in the second sense of the thickness direction,
the second semiconductor element has a second source electrode facing in the second sense of the thickness direction, and a second drain electrode facing in the first sense of the thickness direction,
the first conductive bonding member electrically connects and bonds the first obverse surface and the first drain electrode, and
the second conductive bonding member electrically connects and bonds the third obverse surface and the second drain electrode.

14. The semiconductor device according to claim 13, further comprising: a first metal portion provided between the first source electrode and the third obverse surface, and electrically connects the first source electrode and the third obverse surface; and
a second metal portion provided between the second source electrode and the second obverse surface, and electrically connects the second source electrode and the second obverse surface.

15. The semiconductor device according to claim 13, wherein the first conductive bonding member includes a first base layer made of metal, a first layer, and a second layer, the first layer being provided between the first base layer and the first drain electrode and bonded in direct contact with the first drain electrode at a bonding interface between the first layer and the first drain electrode, the second layer being provided between the first base layer and the first conductive plate and bonded in direct contact with the first conductive plate at a bonding interface between the second layer and the first conductive plate, and
the second conductive bonding member includes a second base layer made of metal, a third layer, and a fourth layer, the third layer being provided between the second base layer and the second drain electrode and bonded in direct contact with the second drain electrode at a bonding interface between the third layer and the second drain electrode, the fourth layer being provided between the second base layer and the third conductive plate and bonded in direct contact with the third conductive plate at a bonding interface between the fourth layer and the third conductive plate.

16. The semiconductor device according to claim 15, wherein each of the first base layer and the second base layer contains aluminum, and
each of the first layer, the second layer, the third layer, and the fourth layer contains silver.

17. The semiconductor device according to claim 1, wherein each of the first conductive plate, the second conductive plate, and the third conductive plate contains copper.
